(19) United States
(12) Patent Application Publication
(10) Pub. No.: US 2026/0096271 A1
(43) Pub. Date: Apr. 2, 2026

(54) LIGHT EMITTING DEVICE

(71) Applicant: GUANGZHOU LUXVISIONS INNOVATION TECHNOLOGY LIMITED, Guangzhou City (CN)

(72) Inventor: Jui Kuang Tsai, Guangzhou City (CN)

(73) Assignee: GUANGZHOU LUXVISIONS INNOVATION TECHNOLOGY LIMITED, Guangzhou City (CN)

(21) Appl. No.: 19/290,342

(22) Filed: Aug. 4, 2025

Related U.S. Application Data
(60) Provisional application No. 63/699,810, filed on Sep. 27, 2024.

(30) Foreign Application Priority Data
Jan. 9, 2025 (CN) 202510037137.2

(51) Int. Cl. H10H 29/851; H01L 25/075; H10H 29/14; H10H 29/24; H10H 29/853

(52) U.S. Cl. CPC H10H 29/8514; H10H 29/142; H10H 29/24; H10H 29/853; H10W 90/00

(57) ABSTRACT

A light emitting device including a substrate, a plurality of light emitting elements, and a plurality of fluorescence modules is provided. The light emitting elements are disposed on the substrate in an array and electrically connected to the substrate. The fluorescence modules are disposed on the substrate and encapsulate the light emitting elements. The fluorescence modules include a first fluorescence module and a second fluorescence module. Colors of the first fluorescence module and the second fluorescence module are different. The first fluorescence module is adjacent to the second fluorescence module, and an interface between the first fluorescence module and the second fluorescence module is transparent.

### CROSS-REFERENCE TO RELATED APPLICATION

This application claims the priority benefit of U.S. provisional application Ser. No. 63/699,810, filed on Sep. 27, 2024 and China application serial no. 202510037137.2, filed on Jan. 9, 2025. The entirety of each of the above-mentioned patent applications is hereby incorporated by reference herein and made a part of this specification.

### BACKGROUND

### Technical Field

The disclosure relates to a light emitting device.

### Description of Related Art

In conventional light emitting diode (LED) device manufacturing, achieving the predefined brightness and color temperature specifications typically necessitates incorporating dimmers and variable resistors on a substrate for multi-stage brightness control of the LEDs, which significantly increases manufacturing costs.

### SUMMARY

The present disclosure provides a light emitting device that can be manufactured at lower cost while achieving predefined brightness and color temperature specifications.

According to one embodiment of the present disclosure, the light emitting device comprises a substrate, a plurality of light emitting elements, and a plurality of fluorescent modules. The light emitting elements are disposed on the substrate in an array and electrically connected to the substrate. The fluorescence modules are disposed on the substrate and encapsulate the light emitting elements. The fluorescence modules include a first fluorescence module and a second fluorescence module. A color of the first fluorescence module is different from a color of the second fluorescence module. The first fluorescence module and the second fluorescence module are adjacent to each other, and an interface between the first fluorescence module and the second fluorescence module is transparent.

In view of the above, the light emitting device provided in one or more embodiments of the disclosure includes a plurality of fluorescence modules of different colors, and the fluorescence modules encapsulate the light emitting elements. By optimizing light emitting wavelengths of the light emitting elements and the colors of the fluorescence modules, the predefined brightness and color temperature specifications can be achieved. With this design, the brightness difference among the light emitting elements can be controlled to less than or equal to 5%, the color temperature difference can be controlled to less than or equal to 5%, and/or the output power difference can be controlled to less than or equal to 5%. In other words, dimmers and variable resistors on the substrate for multi-stage brightness control of the light emitting elements can be eliminated, significantly reducing the manufacturing costs of the light emitting device.

To make the above features of the disclosure more apparent and understandable, embodiments are specifically provided below with detailed explanations in conjunction with the accompanying drawings as follows.

### BRIEF DESCRIPTION OF THE DRAWINGS

FIG. 1A and FIG. 1B are schematic diagrams of a light emitting device according to some embodiments of the disclosure.

FIG. 2A and FIG. 2B are schematic diagrams of a light emitting device according to some embodiments of the disclosure;

FIG. 3 is a schematic diagram of a light emitting device according to some embodiments of the disclosure.

### DETAILED DESCRIPTION OF EMBODIMENTS

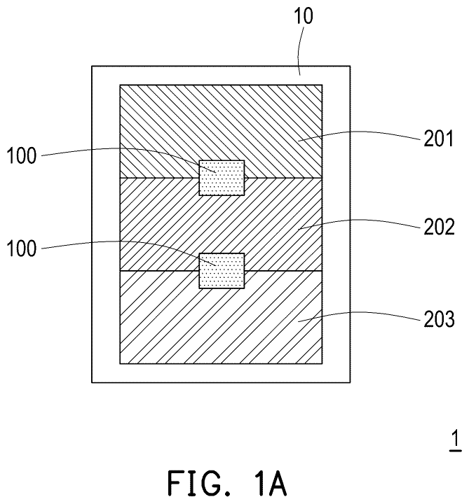

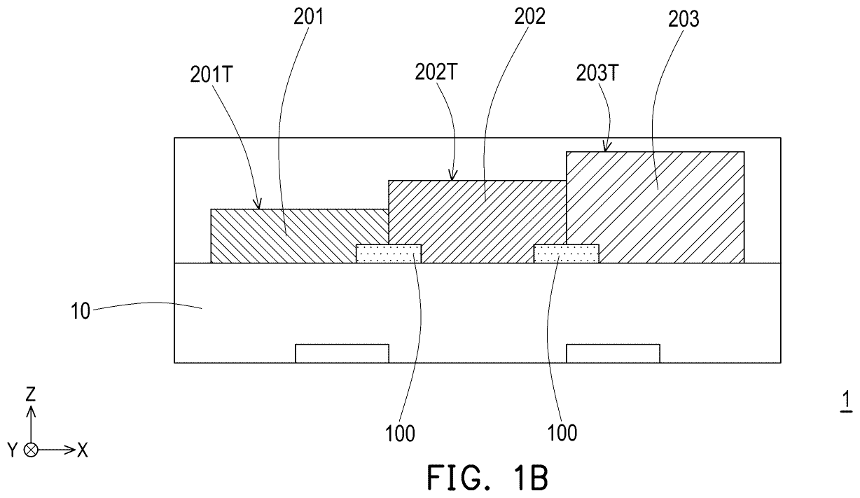

Please refer to FIG. 1A and FIG. 1B, which are schematic diagrams of a light emitting device according to some embodiments of the disclosure.

A light emitting device 1 includes a substrate 10, a plurality of light emitting elements 100, and a plurality of fluorescence modules 201, 202, and 203 sequentially disposed along an X direction. The light emitting elements 100 may be, for instance, LEDs, and are disposed on the substrate 10 in an array and electrically connected to the substrate 10. The fluorescence modules 201, 202, and 203 are disposed on the substrate 10 and encapsulate the light emitting elements 100. Colors of the fluorescence modules 201, 202, and 203 are different. An interface between the fluorescence modules 201 and 202 is transparent, and an interface between the fluorescence modules 202 and 203 is transparent.

In the light emitting device 1 shown in FIG. 1A and FIG. 1B, at least one of the light emitting elements 100 is disposed on the interface between the fluorescence modules 201 and 202, and at least one of the light emitting elements 100 is disposed on the interface between the fluorescence modules 202 and 203, which should however not be construed as limitations in the disclosure. Light from the light emitting elements 100 penetrates through the corresponding fluorescence modules. Through designing light emitting wavelengths of the light emitting elements 100 and the color of each of the fluorescence modules 201, 202, and 203, the predefined brightness and color temperature specifications can be achieved.

In some embodiments, the substrate 10 of the light emitting device 1 may not have the function of regulating output power. Besides, the brightness difference among the light emitting elements 100 can be less than or equal to 5%, the color temperature difference can be less than or equal to 5%, and/or the difference in the output power can be less than or equal to 10%. By disposing the fluorescence modules 201, 202, and 203 of different colors in the light emitting device 1, the predefined brightness and color temperature specifications can be achieved without performing any multi-stage brightness control on the light emitting elements 100. In a comparative example where the multi-stage brightness control needs to be performed on the light emitting elements 100, the light emitting device 1 provided in one or more embodiments of the disclosure may not require any dimmer and variable resistor on the substrate 10. The simple design of the substrate 10 significantly reduces the manufacturing costs of the light emitting device 1.

In the embodiment shown in FIG. 1A and FIG. 1B, the fluorescence modules 201, 202, and 203 have different thicknesses in a normal direction (a Z direction) of the substrate 10. By adjusting the thickness of the fluorescence modules 201, 202, and 203, the color temperature of the light originated from the light emitting elements 100 and penetrating through the fluorescence modules 201, 202, and 203 can be changed. However, this should not be construed as a limitation in the disclosure. In some embodiments, the thickness of the fluorescence modules 201, 202, and 203 in the normal direction (the Z direction) of the substrate 10 may be the same.

In the embodiment shown in FIG. 1A and FIG. 1B, top surfaces 201T, 202T, and 203T of the fluorescence modules 201, 202, and 203 facing away from the substrate 10 are all planar surfaces. However, this should not be construed as a limitation in the disclosure. In some embodiments, at least one of the top surfaces 201T, 202T, and 203T may be a curved surface.

In the embodiment shown in FIG. 1A and FIG. 1B, the top surfaces 201T, 202T, and 203T of the fluorescence modules 201, 202, and 203 facing away from the substrate 10 are parallel to one another. However, this should not be construed as a limitation in the disclosure. In some embodiments, at least one of the top surfaces 201T, 202T, and 203T may be inclined relative to the other top surfaces (i.e., at least one of the top surfaces 201T, 202T, and 203T may not be parallel to the other top surfaces).

In order to fully explain various embodiments of the disclosure, other embodiments of the disclosure will be described below. It must be stated here that the following embodiments follow the reference numbers and partial content of the preceding embodiments, wherein the same reference numbers are used to indicate the same or similar elements, and the explanation of the same technical content is omitted. For the explanation of the omitted parts, reference may be made to the preceding embodiments, and no further explanation will be provided in the following embodiments.

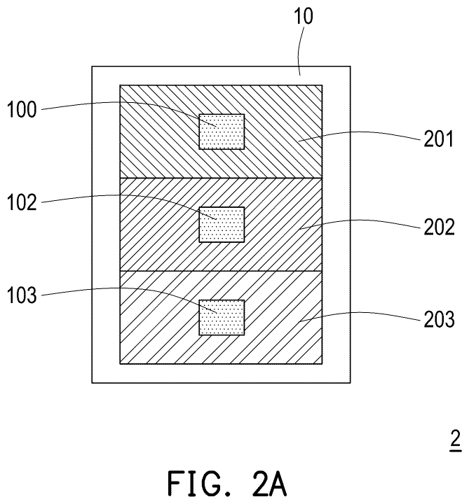

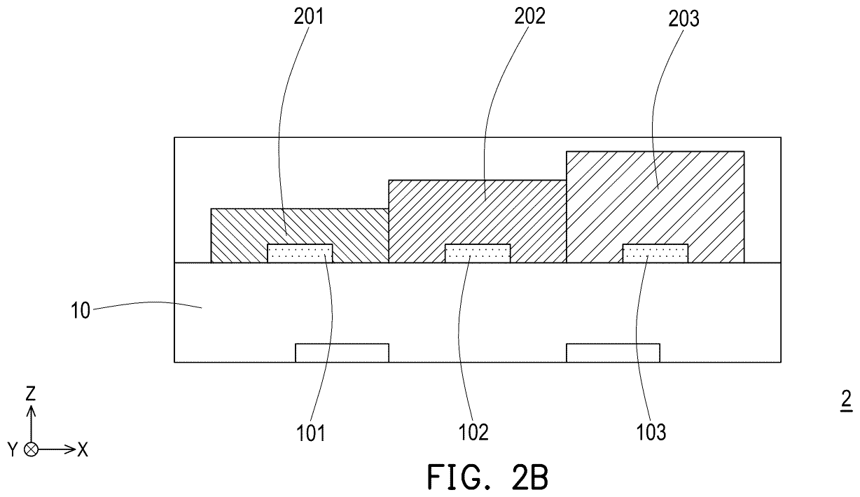

Please refer to FIG. 2A and FIG. 2B, which are schematic diagrams of a light emitting device according to some embodiments of the disclosure.

A light emitting device 2 includes the substrate 10, a plurality of light emitting elements 101, 102, and 103, and the fluorescence modules 201, 202, and 203 sequentially disposed along the X direction. The light emitting elements 101, 102, and 103 are disposed on the substrate 10 in an array and electrically connected to the substrate 10. The fluorescence modules 201, 202, and 203 are disposed on the substrate 10, and encapsulate the light emitting elements 101, 102, and 103. The fluorescence modules 201, 202, and 203 have different colors. The interface between the fluorescence modules 201 and 202 is transparent, and the interface between the fluorescence modules 202 and 203 is transparent.

In the light emitting device 2 shown in FIG. 2A and FIG. 2B, the fluorescence module 201 completely encapsulates the light emitting element 101, the fluorescence module 202 completely encapsulates the light emitting element 102, and the fluorescence module 203 completely encapsulates the light emitting element 103. Light from the light emitting elements 101, 102, and 103 penetrates through the corresponding fluorescence modules. Through designing the light emitting wavelengths of the light emitting elements 101, 102, and 103 and the color of each of the fluorescence modules 201, 202, and 203, the predefined brightness and color temperature specifications can be achieved.

In some embodiments, the substrate 10 of the light emitting device 2 may not have the function of regulating the output power. Besides, the brightness difference among the light emitting elements 101, 102, and 103 can be less than or equal to 5%, the color temperature difference can be less than or equal to 5%, and/or the difference in output power can be less than or equal to 10%. By disposing the fluorescence modules 201, 202, and 203 of different colors in the light emitting device 2, the predefined brightness and color temperature specifications can be achieved without performing any multi-stage brightness control on the light emitting elements 101, 102, and 103. In a comparative example where the multi-stage brightness control is required to be performed on the light emitting elements 101, 102, and 103, the light emitting device 2 provided in one or more embodiments of the disclosure may not require any dimmer and variable resistor on the substrate 10. The simple design of the substrate 10 significantly reduces the manufacturing costs of the light emitting device 2.

In the embodiment shown in FIG. 2A and FIG. 2B, the fluorescence modules 201, 202, and 203 have different thicknesses in the normal direction (the Z direction) of the substrate 10. By adjusting the thickness of the fluorescence modules 201, 202, and 203, the color temperature of the light coming from the light emitting elements 101, 102, and 103 and penetrating through the fluorescence modules 201, 202, and 203 may be changed. However, this should not be construed as a limitation in the disclosure. In some embodiments, the thickness of the fluorescence modules 201, 202, and 203 in the normal direction (the Z direction) of the substrate 10 may be the same.

In the embodiment shown in FIG. 2A and FIG. 2B, the top surfaces 201T, 202T, and 203T of the fluorescence modules 201, 202, and 203 facing away from the substrate 10 are all planar surfaces. However, this should not be construed as a limitation in the disclosure. In some embodiments, at least one of the top surfaces 201T, 202T, and 203T may be a curved surface.

In the embodiment shown in FIG. 2A and FIG. 2B, the top surfaces 201T, 202T, and 203T of the fluorescence modules 201, 202, and 203 facing away from the substrate 10 are parallel to one another. However, this should not be construed as a limitation in the disclosure. In some embodiments, at least one of the top surfaces 201T, 202T, and 203T may be inclined relative to the other top surfaces (i.e., at least one of the top surfaces 201T, 202T, and 203T may not be parallel to the other top surfaces).

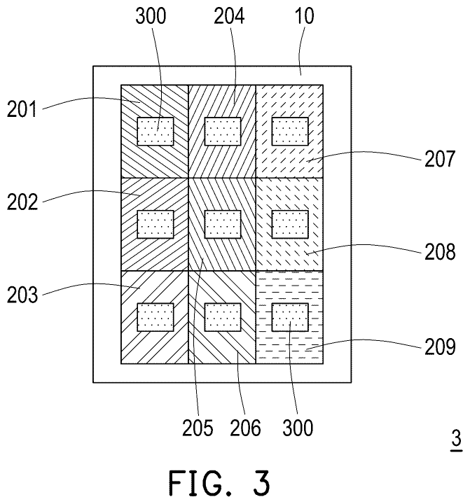

Please refer to FIG. 3, which is a schematic diagram of a light emitting device according to some embodiments of the disclosure.

A light emitting device 3 includes a substrate 10, a plurality of light emitting elements 300, and a plurality of fluorescence modules 201, 202, 203, 204, 205, 206, 207, 208, and 209. The light emitting elements 300 are disposed on the substrate 10 in an array and electrically connected to the substrate 10. The fluorescence modules 201, 202, 203, 204, 205, 206, 207, 208, and 209 are disposed on the substrate 10 and encapsulate the light emitting elements 300. The fluorescence modules 201, 202, 203, 204, 205, 206, 207, 208, and 209 have different colors. An interface between any two adjacent fluorescence modules is transparent.

In the light emitting device 3 shown in FIG. 3, any of the fluorescence modules 201, 202, 203, 204, 205, 206, 207, 208, and 209 completely encapsulates at least one of the light emitting elements 300. Light from the light emitting elements 300 penetrates through the corresponding fluorescence modules. Through designing the light emitting wavelengths of the light emitting elements 300 and the color of each of the fluorescence modules 201, 202, 203, 204, 205, 206, 207, 208, and 209, the predefined brightness and color temperature specifications can be achieved.

In some embodiments, the substrate 10 of the light emitting device 3 may not have the function of regulating the output power. Besides, the brightness difference among the light emitting elements 300 can be less than or equal to 5%, the color temperature difference can be less than or equal to 5%, and/or the difference in the output power can be less than or equal to 10%. Through disposing the fluorescence modules 201, 202, 203, 204, 205, 206, 207, 208, and 209 of different colors in the light emitting device 3, the predefined brightness and color temperature specifications can be achieved without performing any multi-stage brightness control on the light emitting elements 300. In a comparative example where the multi-stage brightness control needs to be performed on the light emitting elements 300, the light emitting device 3 provided in one or more embodiments of the disclosure may not require any dimmer and variable resistor on the substrate 10. The simple design of the substrate 10 significantly reduces the manufacturing costs of the light emitting device 3.

To sum up, the light emitting device provided in one or more embodiments of the disclosure is equipped with a plurality of fluorescence modules of different colors, and the fluorescence modules encapsulate the light emitting elements. Through designing the light emitting wavelengths of the light emitting elements and the color of each of the fluorescence modules, the predefined brightness and color temperature specifications can be achieved. In the aforesaid design, the brightness difference among the light emitting elements can be less than or equal to 5%, the color temperature difference can be less than or equal to 5%, and/or the difference in the output power can be less than or equal to 10%. In other words, it may not be necessary to arrange any dimmer and variable resistor on the substrate for performing the multi-stage brightness control on the light emitting elements, thus significantly reducing the manufacturing costs of the light emitting device.

Although the disclosure has been disclosed in the embodiments as above, it is not intended to limit the disclosure. Any person having ordinary knowledge in the art can make minor modifications and refinements without departing from the spirit and scope of this disclosure. Therefore, the protection scope of this disclosure shall be defined by the appended claims.

What is claimed is:

1. A light emitting device, comprising:
a substrate;
a plurality of light emitting elements, disposed on the substrate in an array and electrically connected to the substrate; and
a plurality of fluorescence modules, disposed on the substrate and encapsulating the light emitting elements,
wherein the fluorescence modules comprise a first fluorescence module and a second fluorescence module, a color of the first fluorescence module is different from a color the second fluorescence module, the first fluorescence module is adjacent to the second fluorescence module, and an interface between the first fluorescence module and the second fluorescence module is transparent.

2. The light emitting device according to claim 1, wherein the light emitting elements comprise a first light emitting element and a second light emitting element, the first fluorescence module completely encapsulates the first light emitting element, and the second fluorescence module completely encapsulates the second light emitting element.

3. The light emitting device according to claim 2, wherein a thickness of the first fluorescence module is different from a thickness of the second fluorescence module in a normal direction of the substrate.

4. The light emitting device according to claim 2, wherein the first fluorescence module comprises a first top surface, the second fluorescence module comprises a second top surface, and the first top surface is not parallel to the second top surface.

5. The light emitting device according to claim 2, wherein the first fluorescence module comprises a first top surface, the second fluorescence module comprises a second top surface, and at least one of the first top surface and the second top surface is a curved surface.

6. The light emitting device according to claim 1, wherein at least one of the light emitting elements is disposed corresponding to the interface between the first fluorescence module and the second fluorescence module.

7. The light emitting device according to claim 6, wherein a thickness of the first fluorescence module is different from a thickness of the second fluorescence module in a normal direction of the substrate.

8. The light emitting device according to claim 6, wherein the first fluorescence module comprises a first top surface, the second fluorescence module comprises a second top surface, and the first top surface is not parallel to the second top surface.

9. The light emitting device according to claim 6, wherein the first fluorescence module comprises a first top surface, the second fluorescence module comprises a second top surface, and at least one of the first top surface and the second top surface is a curved surface.

10. The light emitting device according to claim 1, wherein the fluorescence modules further comprise a third fluorescence module, the second fluorescence module is adjacent to the third fluorescence module, the color of the second fluorescence module is different from a color of the third fluorescence module, and an interface between the second fluorescence module and the third fluorescence module is transparent.

11. The light emitting device according to claim 10, wherein the first fluorescence module, the second fluorescence module, and the third fluorescence module are sequentially disposed along one direction.

12. The light emitting device according to claim 1, wherein a brightness difference among the light emitting elements is less than or equal to 5%.

13. The light emitting device according to claim 1, wherein a color temperature difference among the light emitting elements is less than or equal to 5%.
